(19) United States
(12) Patent Application Publication
(10) Pub. No.: US 2005/0014344 A1
(43) Pub. Date: Jan. 20, 2005

(54) Method of forming well in semiconductor device

(76) Inventor: Myung Gyu Choi, Cheongjoo-Shi (KR)

Correspondence Address: JACOBSON HOLMAN PLLC, 400 SEVENTH STREET N.W., SUITE 600, WASHINGTON, DC, 20004, US

(21) Appl. No.: 10/724,127

(22) Filed: Dec. 1, 2003

(30) Foreign Application Priority Data
Jul. 18, 2003 (KR) 2003-49052

(51) Int. Cl. H01L 21/76

(52) U.S. Cl. 438/433

(57) ABSTRACT

The present invention relates to a method of forming a well in a semiconductor device. After a sidewall oxidization process of a trench formed by a shallow trench isolation technology is performed, an additional ion implantation process is performed. In the above, the additional ion implantation process includes implanting an impurity onto the sidewalls of the trench using a deflected ion beam and implanting the ion by rotating the device 4 times. Therefore, the impurity can be implanted into all the sidewalls of the trench. It is possible to improve characteristics of the device due to formation of a well in which the doping concentration of the impurity ion is uniform.

### BACKGROUND

1. Field of the Invention

The present invention relates to a method of forming a well in a semiconductor device and, more specifically, to a method of forming a well in a semiconductor device capable of improving characteristics of the device, by forming a well in which the doping concentration of an impurity ion is uniform.

2. Discussion of Related Art

As the level of integration in a semiconductor device becomes higher, technology for reducing the isolation region that occupies a significant area of the semiconductor device has been actively developed.

Due to the flatness of the surface of the isolation region, a fine design rule, etc., a shallow trench isolation technology as an isolation technology of a next-generation device having a high level of integration was developed. A trench is formed in a semiconductor substrate by means of the shallow trench isolation technology and silicon oxide or polysilicon into which an impurity is not doped is buried by means of chemical vapor deposition (hereinafter referred to as ‘CVD’) method, thus forming a shallow trench isolation (STI) isolation film.

A well is formed in order to fabricate a device in the semiconductor substrate in which the STI type isolation film is formed. As the level of integration in the semiconductor device is increased, distribution of an impurity ion doping concentration of the well in which the device is fabricated affects characteristics of the device. The impurity ion implanted for formation of the well laterally diffuses upon a thermal process such as a subsequent annealing process, etc. This causes to lower the doping concentration around the isolation film. These conditions are further apparent when a P type well is formed by implanting a P type impurity ion such as boron, etc., which has a small atomic size and a small atomic weight.

Furthermore, in a device employing a STI type isolation film, a well ion implantation process is performed after the STI type isolation film is formed. In this case, the depths that the ions are implanted are quite different due to the step between an active region and a field region. For this reason, distribution of the well concentration is lowered around the isolation film. As such, distribution of the impurity concentration in the well becomes irregular due to lateral diffusion of the impurity ion and the difference in the step of the isolation film. As a result, device characteristics such as a junction leakage current, an inverse narrow width effect, a narrow width effect, and the like. are degraded to adversely affect reliability of the device.

### SUMMARY OF THE INVENTION

The present invention is directed to a method of forming a well in a semiconductor device capable of improving characteristics of the device by forming a well in which a doping concentration of an impurity ion is uniform.

According to a preferred embodiment of the present invention, there is provided a method of forming a well in a semiconductor device, including the steps of forming a trench in a semiconductor substrate using a patterned pad nitride film as an etch mask so that a field region is opened, forming an oxide film along the surface of the trench, performing an additional ion implantation process to form an additional ion implantation layer on the sidewalls of the trench, filling the trench with an insulating material to form a field oxide film, and removing the pad nitride film and then forming a well within the semiconductor substrate by means of a well ion implantation process and a subsequent annealing process.

In the aforementioned of a method of forming a well in a semiconductor device according to another embodiment of the present invention, the additional ion implantation process includes implanting an ion in a tilt of 3 to 10° and rotating the device 4 times. The additional ion implantation process and the well ion implantation process use the same impurity ion.

### BRIEF DESCRIPTION OF THE DRAWINGS

FIGS. 1A to 1F are cross-sectional views for explaining a method of forming a well in a semiconductor device according to a preferred embodiment of the present invention.

### DETAILED DESCRIPTION OF PREFERRED EMBODIMENTS

Now the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later.

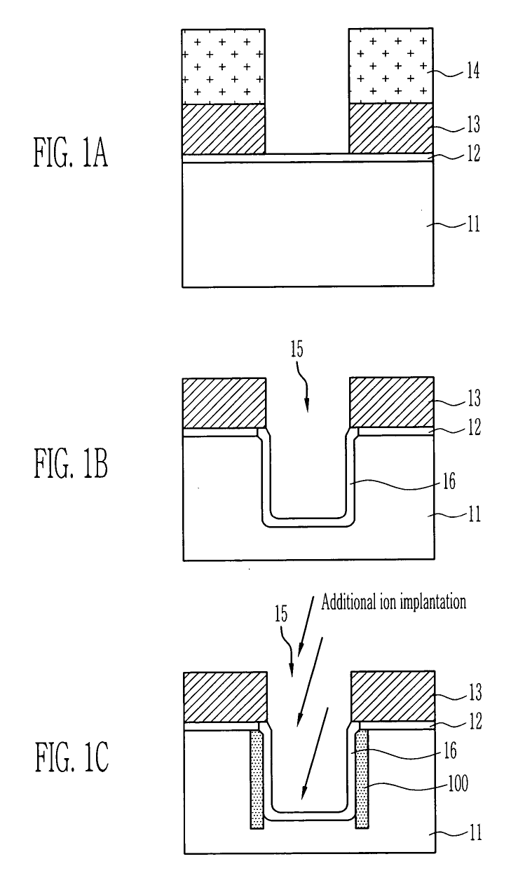

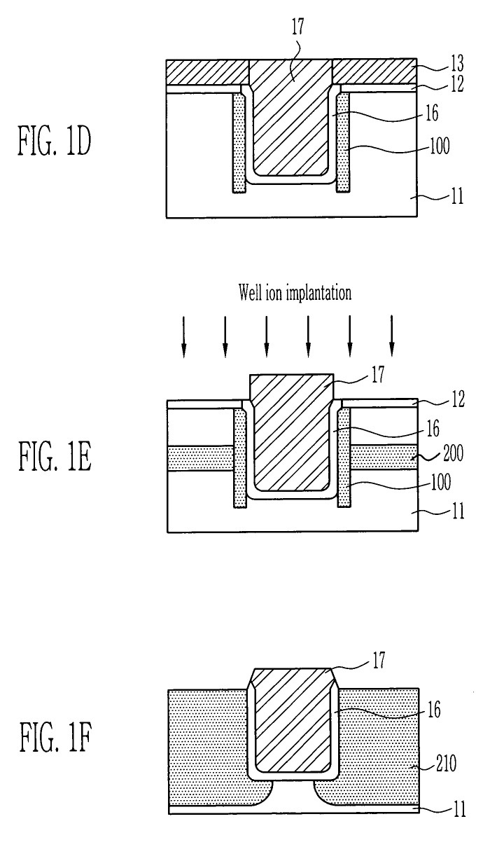

FIGS. 1A to 1F are cross-sectional views for explaining a method of forming a well in a semiconductor device according to a preferred embodiment of the present invention.

Referring to FIG. 1A, a pad oxide film 12 and a pad nitride film 13 are formed on a semiconductor substrate 11. The pad nitride film 13 is patterned by means of an etch process using a photoresist pattern 14 wherein a field region is opened as an etch mask.

In the above, the pad oxide film 12 is formed in thickness of 50 to 150 Å and is for mitigating stress applied to the semiconductor substrate 11 and the pad nitride film 13. The pad nitride film 13 is formed in thickness of 1000 to 2000 Å.

By reference to FIG. 1B, after removing the photoresist pattern 14, the pad oxide film 12 and the semiconductor substrate 11 are etched in a given depth by means of an etch process using the patterned pad nitride film 13 as an etch mask, thereby forming a trench 15. After performing a blanket cleaning process, a sidewall rounding oxidation process is performed to form a sidewall oxide film 16 on the trench 15.

In the above, the trench 15 is formed 2500 to 4000 Å in a depth by anisotropically etching the semiconductor substrate 11 using reactive ion etching, plasma etch, etc. The blanket cleaning process is performed in a SC-1 solution of 50° C. for about 10 minutes and then in a diluted HF solution for about 360 seconds. In the sidewall rounding oxidation process, the sidewall oxide film 16 is formed in thickness of 100 to 200 Å by means of a dry oxidization process at a temperature of about 1050° C.

With reference to FIG. 1C, an additional ion implantation process is performed to form additional ion implantation layers 100 in the semiconductor substrate 11, which form the sidewalls of the trench 15.

In the above, since the ion is implanted in a tilt of 3 to 10° in the additional ion implantation process, the impurity ion is implanted only into the sidewall of the trench 15. The additional ion implantation layers 100 are formed on all the sidewalls of the trench 15 by rotating the device 4 times. In this case, in case where a P type well is formed, an impurity ion of a P type is used. In case where an N type well is formed, an impurity ion of an N type is used. The dose of the impurity ion that is additionally implanted is implanted as much amount as the concentration of the well is lowered, considering the concentration of the well that is lowered upon an existing process. As the amount of the concentration of the well every device is different, the additional ion implantation amount is not limited to a specific value.

Referring to FIG. 1D, an insulating material such as oxide, etc. is deposited enough to bury the trench 15. A chemical mechanical polishing process is then performed to form a field oxide film 17 being a STI isolation film.

By reference to FIG. 1E, after the remained pad nitride film 13 is removed, a well ion implantation process is performed to form a well ion burial layer 200 in a given depth of the semiconductor substrate 11.

In the above, the well ion burial layer 200 can be formed to have an adequate range of projection (Rp) in a given depth of the substrate 11, by adjusting ion implantation energy upon the well ion implantation process. The impurity ion used in the well ion implantation process is same as the impurity ion used in the additional ion implantation process.

With reference to FIG. 1F, a pad oxide film 12 existing on the surface of the semiconductor substrate 11 is removed through a cleaning process, etc. The impurity ion existing in the well ion burial layer 200 and the additional ion implantation layer 100 are diffused by an annealing process such as a subsequent annealing process, etc, so that a well 210 is formed within the semiconductor substrate 11. As the impurity ion of the additional ion implantation layer 100 compensates for the amount of the ion that is lost around the field oxide film 17, the whole impurity ion doping concentration of the well 210 is uniform.

According to the present invention described above, after a sidewall oxidization process of a trench that is formed by a shallow trench isolation technology is performed, an additional ion implantation process is performed. A well concentration slop phenomenon that distribution of the well concentration in an active region is gradually lowered than the impurity concentration at the center of the well as it approaches a field oxide film. Therefore, there is an advantage that device characteristics such as a junction leakage current, an inverse narrow width effect, a narrow width effect, etc. are improved to improve reliability of the device.

Although the foregoing description has been made with reference to the preferred embodiments, it is to be understood that changes and modifications of the present invention may be made by the ordinary skilled in the art without departing from the spirit and scope of the present invention and appended claims.

1. A method of forming a well in a semiconductor device, comprising the steps of:
forming a trench in a semiconductor substrate using a patterned pad nitride film as an etch mask so that a field region is opened;
forming an oxide film along the surface of the trench;
performing an additional ion implantation process to form an additional ion implantation layer on the sidewalls of the trench;
filling the trench with an insulating material to form a field oxide film; and
removing the pad nitride film and then forming a well within the semiconductor substrate by means of a well ion implantation process and a subsequent annealing process.

2. The method as claimed in claim 1, wherein the additional ion implantation process includes implanting an ion in a tilt of 3° to 10° and rotating the device 4 times.

3. The method as claimed in claim 1, wherein the additional ion implantation process and the well ion implantation process use the same impurity ion.
